(19) United States
(12) Patent Application Publication
(10) Pub. No.: US 2024/0310446 A1
(43) Pub. Date: Sep. 19, 2024

(54) METHODS OF REAL-TIME ACTIVE MEASUREMENT FOR ELECTROCHEMICAL SYSTEMS

(71) Applicant: REJOULE INCORPORATED, Signal Hill, CA (US)

(72) Inventors: Hugo LEDUC, Signal Hill, CA (US); Russell OKAMURA, Signal Hill, CA (US); Eru KYEYUNE NYOMBI, Signal Hill, CA (US); Kenny HUYNH, Signal Hill, CA (US); Steven CHUNG, Signal Hill, CA (US)

(21) Appl. No.: 18/264,058

(22) PCT Filed: Jan. 26, 2022
(86) PCT No.: PCT/US2022/013930

§ 371 Date: Aug. 2, 2023

Related U.S. Application Data
(60) Provisional application No. 63/146,348, filed on Feb. 5, 2021.

(51) Int. Cl. G01R 31/367; G01R 31/388; G01R 31/389; G01R 31/392; H01M 10/44; H01M 10/48; H02J 7/00

(52) U.S. Cl. CPC G01R 31/367; G01R 31/388; G01R 31/389; G01R 31/392; H01M 10/441; H01M 10/482; H02J 7/0014; H02J 7/0048; H02J 7/005

(57) ABSTRACT

Provided herein are systems and methods for rapid and real-time assessment of active measurements and for active balancing of a rechargeable electrochemical storage system. Certain systems and methods provided herein are set forth for individually electrically addressing certain electrochemical elements amongst a collection of batteries. Certain systems and methods provided herein are set forth for individually electrically addressing certain electrochemical elements amongst a collection of electrochemical elements. Certain systems and methods provided herein are set forth for analyzing one or more battery cells amongst a collection of battery cells and/or battery modules and/or battery packs. Certain systems and methods provided herein are set forth for analyzing one or more electrochemical elements amongst a collection of electrochemical elements.

### CROSS-REFERENCE TO RELATED APPLICATIONS

This application claims the benefit of, and priority to, U.S. Provisional Patent Application No. 63/146,348, filed Feb. 5, 2021, the entire contents of which are herein incorporate by reference in their entirety for all purpose.

### STATEMENT OF GOVERNMENT RIGHTS

This invention was made with government support under contract No. 1842957 awarded by the National Science Foundation. The government has certain rights in the invention.

### FIELD

The present disclosure concerns electrochemical elements, e.g., lithium-ion secondary or traction batteries, and related electrochemical storage management systems, e.g., battery management systems.

### BACKGROUND

There is an unmet need for quickly and accurately assessing state-of-health and state-of-charge in a rechargeable battery. There is also an unmet for analyzing one or more battery cells amongst a collection of battery cells and battery modules. Set forth herein are solutions to these and other problems in the related field.

### SUMMARY

In one example, set forth herein is a method for scheduling a measurement, in which the methods includes (a) providing, or having provided, at least two electrochemical elements; (b) inputting into an active parameter and element selector (APAES):
(1) a passive current measurement (Iₚ);
(2) an asynchronous output from a system controller;
(3) an output from a voltage-distribution calculator (V_{d});
(4) a first output from an active parameter distribution calculator (Z_{d});
(5) an output from a temperature model (T_{d}); or
(6) any combination of (1), (2), (3), (4), and/or (5);

(c) generating from the APAES:
(1) an active parameter output (D′); and
(2) a selected electrochemical element (Y′); and
(d) inputting D′ and Y′ into an active parameter actuator and calculator; (e) performing, or having performed, an active parameter measurement to generate at least one active parameters output (Zₘ) from Y′; (f) inputting Zₘ into an active parameter distribution calculator to generate a second active parameter distribution (Z_{d}′); (g) inputting V_{d}, Z_{d}′, and T_{d} into a state-of-health (SOH) model; and (h) generating an SOH model output (SOH_{d}) from the SOH model.

In a second example, set forth herein is a method for actively balancing state-of-charge (SOC), voltage (V), or both, between two or more electrochemical elements using a minimization function, including: (a) providing, or having provided, at least two electrochemical elements; (b) generating from an active parameter and element selector (APAES) a selected electrochemical element (Y′); (c) providing, or having provided, an EIS-derived impedance measurement as an active parameter (Zₘ) of Y′; (d) providing, or having provided, one or more temperature look-up tables (LUT) as a function of Zₘ, state-of-charge (SOC), state-of-health (SOH), or a combinations thereof; (e) estimating the temperature of Y′ using the LUT; (f) estimating state-of-health (SOH) of Y′ using the LUT; (g) selecting a module open circuit voltage (OCV) LUT based on the estimated SOH and estimated temperature in steps (e) and (f); (h) generating a predicted SOC, V, or both, for at least two of the two or more electrochemical elements based on the OCV LUT selected in step (g); and (i) actively balancing at least one of SOC, V, or SOH for the two or more electrochemical elements using a minimization function.

In a third example, set forth herein, is a method for analyzing and balancing a battery in real-time, including: (a) selecting at least one electrochemical element in a collection of electrochemical elements as an output from a decision calculator by inputting into the decision calculator a Distribution of at least two or more of the electrochemical elements; wherein the Distribution is a function of:
(1) the output from a voltage-distribution calculator (V_{d});
(2) the output from an active parameter distribution calculator (Z_{d});
(3) the output from a temperature model (T_{d}); or
(4) a combination thereof;
(b) generating a SOC, SOH, or V for the selected electrochemical element using EIS; and (c) active balancing SOC, SOH, V, or a combination thereof for two or more of the electrochemical elements; and (d) repeating steps (a), (b), and (c) at least once.

### BRIEF DESCRIPTIONS OF THE DRAWINGS

FIG. 1 shows a diagram of a battery management system (BMS) monitoring board for a battery module.

FIG. 2 shows a method for using an active measurement system in a real-time system for the purpose of temperature monitoring and/or state-of-health (SOH) estimation.

FIG. 3 shows a plot of a battery cell voltage v. state-of-charge (%).

FIG. 4 shows a diagram of a real-time method that uses both passive and active measurements set forth herein.

FIG. 5 shows a plot of alternative current (AC) current (I) and AC voltage (V) as a function of time for a device-under-test (DUT).

FIG. 6 shows an output plot of electrochemical impedance spectroscopy for each frequency point in Hertz (Hz) plot for a DUT.

FIG. 7 shows a method for using a minimization function for the purpose of electrochemical element balancing based on the output of the active measurement system.

### DETAILED DESCRIPTION

### I. Definitions

As used herein, the phrase “electrochemical cell” refers to the lowest denominator of an electrochemical energy storage device often comprising an anode, a cathode, a separator, and an electrolyte. An electrochemical cell may also include contact terminals (also known as current collectors). Anode may also be referred to as a negative electrode. Cathode may also be referred to as a positive electrode.

As used herein, the phrase “electrochemical element” refers to a component of an electrochemical cell, a battery cell, or a collection of battery cells. An electrochemical element may include a current collector, an anode (or negative electrode), a cathode (or positive electrode), an electrolyte, or a separator. An electrochemical element may also include just a cathode. An electrochemical element may also include just an anode. An electrochemical element may also include a battery cell. An electrochemical element may also include a battery module. An electrochemical element may also include a battery string or pack or any association of electrochemical element associated in series or parallel. Unless specified otherwise explicitly, an electrochemical element refers to a battery cell, in which the battery cell includes at least a cathode, an anode, an electrolyte, and a separator.

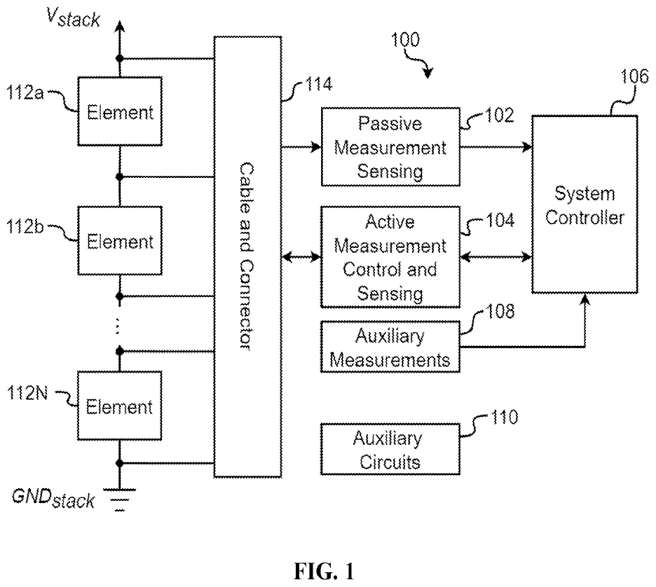

As used herein, the phrase “selecting at least one active parameters output (Zₘ) from Y′,” refers to generating a decision to measure an active parameter from a device-under-test (DUT), in which the DUT was selected based on a decision algorithm. For example, “selecting at least one active parameters output (Zₘ) from Y′ may include deciding to measure impedance on cell 112b as shown in FIG. 1.

As used herein, the phrase “active parameter and element selector (APAES),” refers to a function or piece of software that makes decisions based on inputs. These decisions include which active parameter to measure, e.g., impedance, reactance, current, or voltage. These decisions also include which electrochemical element in a collection of electrochemical elements to measure. For example, FIG. 1 shows a collection of battery cells (112a), (112b) to (112N) configured in parallel or series. The APAES generates a decision to address one or more of these cells for a measurement. The inputs may include temperature, voltage, current, or other active parameter measurements as detailed below.

As used herein, “asynchronous output from a system controller,” refers to a signal generated by a system controller which is not dependent on the input for a given process step. For example, a fire or safety warning signal identifying an electrochemical element as combusting is a non-limiting example of an asynchronous output from a system controller.

As used herein, the phrase “voltage-distribution calculator,” refers to a function or piece of software that makes decisions about the distribution of voltage values amongst targeted DUT electrochemical elements based on measured voltage (Vₘ) inputs.

As used herein, the phrase “active parameter distribution calculator,” refers to a function or piece of software that makes decisions about the distribution of active parameters values amongst targeted DUT electrochemical elements based on active parameters inputs.

As used herein, the phrase “output from an active parameter distribution calculator (Z_{d}),” refers to the distribution generated by an active parameter distribution calculator. For example, the output may be a spatial resolution of active parameters for a series of targeted DUTs.

As used herein, the phrase “active parameter distribution (Z_{d} or Z_{d}′),” refers to an output from an function or piece of software that associates active parameter values with electrochemical elements. In some examples, Z_{d} is a spatial distribution of active parameter values for each measured electrochemical element.

As used herein, the phrase “active parameter output (D′),” refers to a specific active parameter from a list of active parameters. For example, D′ may be impedance but could have been selected from impedance, reactance, voltage, current, or capacity.

As used herein, the phrase “active parameter actuator and calculator,” refers to a function or piece of software that makes decisions about which active parameters to measure for a target DUT electrochemical element based on inputs, such as, but not limited to, active parameters, measured temperatures, or outputs from a SOH, SOC, or temperature model.

As used herein, the phrase “temperature model” is a function that is based on already-acquired data associating the temperature of an electrochemical element with an active parameter that can be measured for that electrochemical element.

As used herein, the phrase “output from a temperature model (T_{d}),” refers to the value generated when a temperature model is used to associate the temperature of an electrochemical element with an active parameter that can be measured for that electrochemical element.

As used herein, a “state-of-health (SOH) model” is a function that is based on already-acquired data associating the SOH of an electrochemical element with an active parameter that can be measured for that electrochemical element.

A s used herein the phrase “SOH_{d} is generated by inputting a measured or determined state-of-health (SOH) into a SOH model,” refers to a process by which a function or piece of software associates SOH values with electrochemical elements. In some examples, SOH_{d} is a spatial distribution of SOH values for each measured electrochemical element.

As used herein, the phrase “internal-temperature-calculator,” refers to a function or piece of software that makes decisions about the internal-temperature of an electrochemical element based on inputs, such as, but not limited to, active parameters, measured temperatures, or outputs from a SOH, SOC, or temperature model.

As used herein, the term “module” refers to a plurality of electrochemical cells connected together in a combination of series and/or parallel configurations.

As used herein, the term “pack,” refers to a plurality of cells connected together in a combination of series and/or parallel configurations, and may also refer to a plurality of modules connected together in a combination of series and/or parallel configurations, depending on the battery system construction and configuration. A pack refers to a combination of modules unless specified to the contrary. A pack may also refer to a combination of multiple battery strings, where a string may be a combination of modules. A plurality of electrochemical elements electrically connected together in some series and/or parallel configuration may be referred to as an electrochemical storage system.

As used herein, the term “electrochemical storage management system” refers to a hardware and software system, typically electronic, that monitors, controls, and protects an electrochemical storage system.

As used herein, the phrase “impedance measurement,” refers to the measurement of Alternative Current (AC) impedance of an electrochemical cell, a module, or a pack via a periodic or non-periodic excitation signal at one or more frequencies.

As used herein, the phrase “voltage-data processor,” refers to a software function that aggregates a plurality of voltage measurements either in a raw or processed form.

As used herein, the phrase “temperature-data processor,” refers to a software function that aggregates a plurality of temperature measurements either in a raw or processed form.

As used herein, the phrase “impedance-data processor,” refers to a software function that aggregates a plurality of impedance measurements either in a raw or processed form.

As used herein, the phrase “decision calculator,” refers to a function or piece of software that makes decisions based on inputs.

As used herein, the phrase “active characterization,” refers to using an external excitation on a device-under-test (DUT) and measuring the response to that external excitation for the purpose of electrochemical cell characterization. Examples include but are not limited to electrochemical impedance spectroscopy (EIS), pulse testing, hybrid pulse power characterization (HPPC), galvanostatic intermittent titration technique (GITT) and potentiostatic intermittent titration technique (PITT).

As used herein, the phrase “passive characterization,” refers to using passive measurements on the DUT for the purpose of electrochemical element characterization. Examples include but are not limited to measuring voltage, pressure, or temperature of an electrochemical element.

As used herein, the phrase “passive voltage measurement (Vp),” refers to a passive measurement of voltage on the DUT for the purpose of electrochemical element characterization or monitoring.

As used herein, the phrase “passive current measurement (Iₚ),” refers to a passive measurement of current on the DUT for the purpose of electrochemical element characterization or monitoring.

As used herein, the phrase “passive temperature measurement (Tp),” refers to a passive measurement of temperature on the DUT for the purpose of electrochemical element characterization or monitoring. Tp typically refers to an electrochemical element surface temperature, where a passive temperature sensing device is placed on the surface of the DUT. An example of a passive temperature sensing device is a thermistor. Another example of a passive temperature sensing device is a thermistor. A system may comprise at least one passive temperature sensing device.

As used herein, the phrase “electrochemical impedance spectroscopy (EIS),” refers to a test technique where a non-dc electrical signal is used to excite the DUT, and a resulting response signal from the electrochemical element, is measured. The excitation signal may contain a single frequency, or it may contain multiple frequencies. The excitation signal may also contain a dc component. The combination of the excitation signal and the response signal are then used to compute the impedance of the DUT.

As used herein, the phrase “pulse test,” refers to driving a unidirectional power pulse excitation signal into the DUT for the purpose of measuring the response of the device to the excitation. In the event a galvanostatic pulse is used, the voltage response of the DUT is measured. In the event that a potentiostatic pulse is used, the current response of the DUT is measured.

As used herein, the phrase “hybrid-pulse power characterization (HPPC)” refers to an analytical test which includes driving a series of charge and/or discharge power pulse excitation signals into the DUT for the purpose of measuring the response of the DUT to the excitation.

As used herein, the phrase “galvanostatic intermittent titration technique (GITT) refers to driving a series of current pulses into the DUT, where each current pulse is followed by some rest time for the purpose of characterizing the DUT through measuring the DUT response to the current pulses.

As used herein, the phrase “potentiostatic intermittent titration technique (PITT) refers to driving a series of voltages pulses into the DUT, where each voltage pulse is followed by some rest time for the purpose of characterizing the DUT through measuring the DUT response to the voltage pulses.

As used herein, the phrase “equivalent circuit element” refers to a combination of electrical circuit elements connected together in some configuration, where the behavior of these electrical circuit elements is equivalent or representative to that of a physical phenomenon.

As used herein, the phrase “internal temperature,” refers to the temperature of the inside of an electrochemical element, as opposed to electrochemical element surface temperature or ambient temperature.

As used herein, the phrase “ambient temperature,” refers to the surrounding temperature of an environment.

As used herein, the phrase “surface temperature,” refers to the temperature of a device as measured on the surface of that device.

As used herein, the phrase “minimization function,” refers to a software optimization function which reduces the difference between the outputs of two functions (e.g., a prediction function and a measurement function, a target SOC difference and a measured SOC difference, a target voltage difference and a measured voltage difference, or a target SOH difference and a measured SOH difference) and also applies to a similar maximization function that increases the difference between the two outputs of two functions. The difference between the prediction function and the measurement function is referred to herein as σ. In some instances, σ may also include common statistical parameters such as standard deviation and variance.

### II. Systems

Set forth herein are systems for implementing the methods also set forth in the instant disclosure. An example system is set forth in FIG. 1.

In some examples, set forth herein, is a system substantially as shown in FIG. 1.

FIG. 1 shows an embodiment of an active measurement system (100). This active measurement system (100) may be used as a battery management system (BMS) board for a module which includes electrochemical battery cells. The BMS board includes a Passive Measurement Sensing block (102). One function of the Passive Measurement Sensing block (102) is to measure and monitor passive measurements such as, but not limited to, electrochemical element voltage, electrochemical element current, electrochemical element surface temperature, electrochemical element ambient temperature, electrochemical element pressure, or a combination thereof. The board includes an Active Measurement Control and Sensing block (104). One function of the Active Measurement Control and Sensing block (104) is to control the electrical or electromechanical actuators that perform active measurements. Another function of the Active Measurement Control and Sensing block (104) is to convert active measurements into interpretable analog or digital signals. The board includes a System Controller (106) that manages all aspects of the active measurement system. The board includes an Auxiliary Measurement(s) (108) and an Auxiliary Circuit(s) (110) that may include additional sensors or circuits. The Passive Measurement Sensing block (102) and Active Measurement Control and Sensing block (104) may contain hardware or software filters. Filters may be accomplished with analog or digital methods. Analog or digital filtering methods may include low pass filters, high pass filters, band pass filters, notch filters, finite impulse response filters, infinite impulse response filters, multirate filters, adaptive filters, or other such methods that reject unwanted noise in a signal. Filtering methods may also include outlier detection methods and anomaly detection methods.

The active measurement system performs active measurements and monitors passive measurements of the device under test-electrochemical elements (112). Electrochemical elements (112) includes N elements (112a), (112b) to (112N) configured in parallel or series. The electrochemical element measurements are captured through a Cable and Connector (114), which represents a means for the active measurement system (100) to electrically connect to and access the electrochemical elements (112). The series-connected electrochemical elements make up a voltage Vstack, referenced to the stack ground GNDstack.

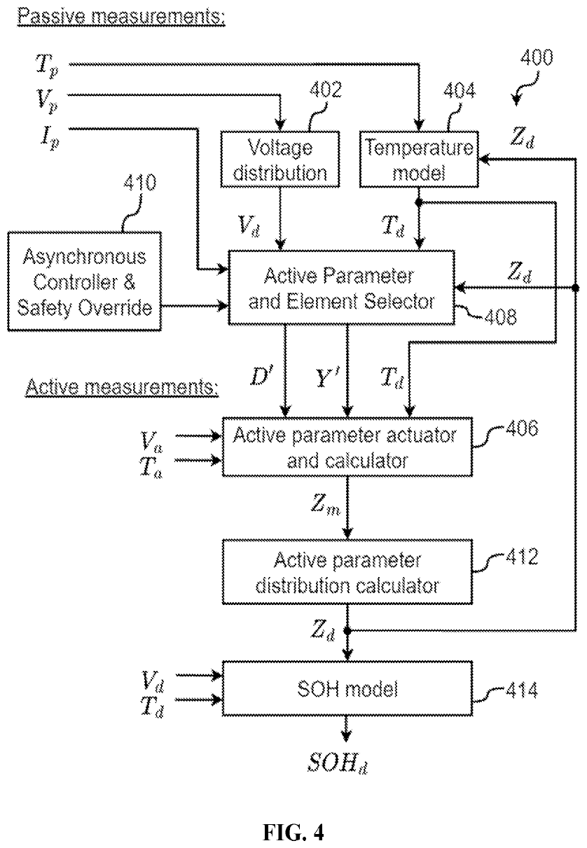

Set forth herein are systems for implementing the methods also set forth in the instant disclosure. An example system is set forth in FIG. 4.

FIG. 4 shows a system for a real-time active measurement system (400). The system includes a Voltage Distribution calculator (402). One function of the Voltage Distribution calculator (402) is to generate a Voltage distribution (V_{d}) by analyzing passive voltage measurements (Vₚ) as inputs. V_{d} may represent a spatial distribution of voltages amongst a group of electrochemical cells in a module. V_{d} may represent a spatial distribution of voltages amongst a group of modules in a pack. The system includes a Temperature model calculator (404). One function of the Temperature model calculator (404) is to generate a Temperature distribution (T_{d}) by analyzing passive temperature measurements (Tp) as inputs. T_{d} may represent a spatial distribution of temperatures amongst a group of electrochemical cells in a module. T_{d} may represent a spatial distribution of temperatures amongst a group of modules in a pack. Another function of the Temperature model calculator (404) is to generate a Temperature distribution (Td) by an active parameter (Zd) as an input. Another function of the Temperature model calculator (404) is to generate a Temperature distribution (T_{d}) by analyzing passive temperature measurements (Tₚ) and an active parameter (Z_{d}) as inputs. The system includes an Active Parameter and Element Selector (408). One function of the Active Parameter and Element Selector (408) is to generate an active parameter output (D′); and a selected electrochemical element (Y′). The Y′ is one electrochemical element in a group of electrochemical elements. For example, the electrochemical element may be any one of elements (112a) or (112b) to (112N), as shown in FIG. 1. The system includes an Active parameter actuator and calculator (406) that is used to generate active parameters (Zₘ) using D′, Y′, and T_{d} as inputs and analyzing these inputs. The system also includes an Asynchronous Controller and a Safety Override (410). One function of the Asynchronous Controller and a Safety Override is to shut down the system if an unsafe condition is determined. For example, a system controller may detect a fire and send a signal to shut down the system, in which the sent signal would be an asynchronous signal sent from a system controller. The system includes an Active parameter distribution calculator (412). One function of the Active parameter distribution calculator (412) is to generate an active parameter distribution (Z_{d}) using measured active parameters (Zₘ) as inputs. The system includes the State-of-health (SOH) model (414). One function of the SOH model (414) is to generate a state-of-health output (SOH_{d}) using measured active parameter distribution (Z_{d}) as inputs.

### III. Methods

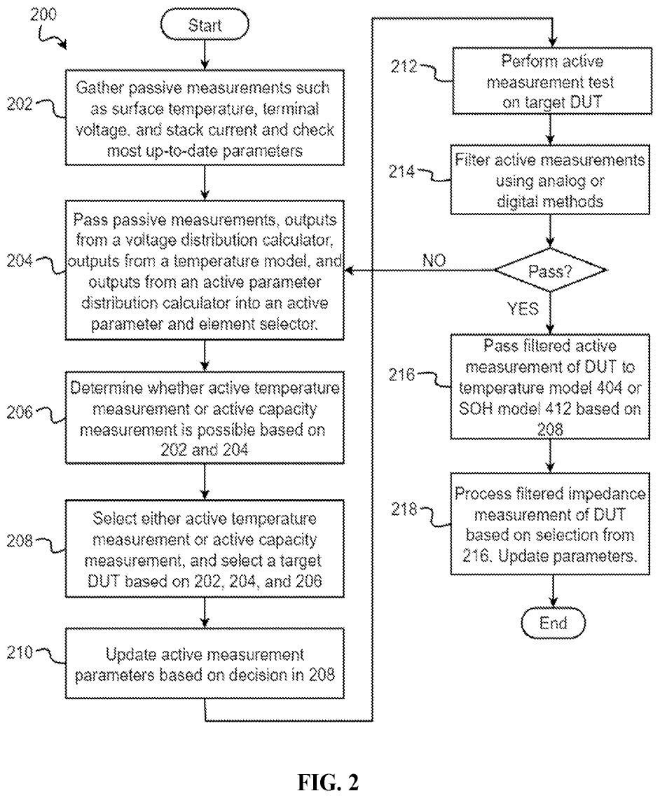

In some examples, set forth herein, is a method substantially as shown in FIG. 2.

In some other examples, set forth herein, is a method substantially as shown in FIG. 4.

In one example, set forth herein is a method for scheduling a measurement, in which the methods includes (a) providing, or having provided, at least two electrochemical elements; (b) inputting into an active parameter and element selector (APAES):
(1) a passive current measurement (Iₚ);
(2) an asynchronous output from a system controller;
(3) an output from a voltage-distribution calculator (V_{d});
(4) a first output from an active parameter distribution calculator (Z_{d});
(5) an output from a temperature model (T_{d}); or
(6) a combination of (1), (2), (3), (4), and (5);
(c) generating from the APAES:
(1) an active parameter output (D′); and
(2) a selected electrochemical element (Y′); and
(d) inputting D′ and Y′ into an active parameter actuator and calculator; (e) performing, or having performed, an active parameter measurement to generate at least one active parameters output (Zₘ) from Y′; (f) inputting Zₘ into an active parameter distribution calculator to generate a second active parameter distribution (Z_{d}′); (g) inputting V_{d}, Z_{d}′, and T_{d} into a state-of-health (SOH) model; and (h) generating an SOH model output (SOH_{d}) from the SOH model.

In some examples, including any of the foregoing, step (e) comprises analyzing Y′ by a measurement selected from the group consisting of electrochemical impedance spectroscopy (EIS), pulse test, high-pulse power characterization (HPPC), galvanostatic intermittent titration technique (GITT), potentiostatic intermittent titration technique (PITT), and combinations thereof.

In some other examples, including any of the foregoing, Zₘ is an impedance measurement.

In other examples, including any of the foregoing, Zₘ is measured by EIS.

In certain other examples, including any of the foregoing, the analysis includes both a discharge pulse and a charge pulse.

In some examples, including any of the foregoing, the method includes measuring the temperature, voltage, or impedance of Y′.

In some other examples, including any of the foregoing, the at least two electrochemical elements are cells within a module.

In other examples, including any of the foregoing, the at least two electrochemical elements are in series.

In certain other examples, including any of the foregoing, the at least two electrochemical elements are in parallel.

In some examples, including any of the foregoing, the real-time active parameter and element selector comprises a filter.

In some other examples, including any of the foregoing, the filter is a Kalman filter (KF).

In other examples, including any of the foregoing, the filter is an extended Kalman filter (EKF).

In some other examples, including any of the foregoing, the filter is a linear or nonlinear joint probability distribution estimation.

In certain other examples, including any of the foregoing, the method includes generating from the APAES a selected Y′ is as a function of a:
(i) local maximum voltage (V), local minimum V, or median V;
(j) local maximum temperature (T), local minimum T, median T, or certain electrochemical elements;
(k) local maximum impedance (Z), local minimum Z, or median Z; or
(l) combination of (i), (j), or (k).

In some examples, the local maximum, local minimum, mean, or median is for an electrochemical element. In some other examples, the local maximum, local minimum, or median is for a collection of electrochemical elements. In some examples, the local maximum, local minimum, or median is for a battery cell. In some other examples, the local maximum, local minimum, or median is for a collection of battery cells. In some examples, the local maximum, local minimum, or median is for a module. In some examples, the local maximum, local minimum, or median is for a collection of modules. In some other examples, the local maximum, local minimum, or median is for a pack.

In some examples, including any of the foregoing, (k) is a function of a frequency or is a function of a preset group of frequencies.

In some examples, including any of the foregoing, (k) is a function of a frequency or is a function of a variable group of frequencies.

In certain other examples, including any of the foregoing:
(m) V_{d} is generated by inputting a measured voltage (Vₘ) or passively determined voltage (Vₚ) into a voltage-distribution-calculator;
(n) Zₘ is generated by inputting an active voltage measurement (Vₐ) or active current measurement (Iₐ), or both, and Td, into an active parameter actuator and calculator;
(o) T_{d} is generated by inputting a passively measured temperature (Tₚ) and Z_{d}, or Z_{d}′ into a temperature model;
(p) Z_{d} or Z_{d}′ is generated by inputting Zₘ into an active parameter distribution calculator; or
(q) SOH_{d} is generated by inputting a measured or determined state-of-health (SOH) into a SOH model.

In certain other examples, including any of the foregoing:
(m) V_{d} is generated by inputting a measured voltage (Vₘ) or passively determined voltage (Vₚ) into a voltage-distribution-calculator;
(n) Zₘ is generated by inputting an active voltage measurement (Vₐ) or active current measurement (Iₐ), or both, and T_{d}, into an active parameter actuator and calculator;
(o) T_{d} is generated by inputting a passively measured temperature (Tₚ) and Z_{d}, or Z_{d}′ into a temperature model;
(p) Z_{d} or Z_{d}′ is generated by inputting Zₘ into an active parameter distribution calculator; and
(q) SOH_{d} is generated by inputting a measured or determined state-of-health (SOH) into a SOH model.

In some examples, including any of the foregoing:
Vₘ or Vₚ is selected from cell voltage, a module voltage, a pack voltage, or a combination thereof;
Zₘ is selected from impedance, reactance, an equivalent circuit element from a model for one or more of the at least two electrochemical elements, or a combination thereof;
Tₚ is selected from an electrochemical element temperature or combinations of electrochemical element temperatures; or
SOH_{d} is determined for an electrochemical element by inputting Z_{d}, T_{d}, V_{d}, Ip, or a combination thereof, into an SOH model.

In some examples, including any of the foregoing:
Vₘ or Vₚ is selected from cell voltage, a module voltage, a pack voltage, or a combination thereof;
Zₘ is selected from impedance, reactance, an equivalent circuit element from a model for one or more of the at least two electrochemical elements, or a combination thereof;
Tₚ is selected from an electrochemical element temperature, or combinations of electrochemical element temperatures; and SOH_{d} is determined for an electrochemical element by inputting Z_{d}, T_{d}, V_{d}, Iₚ, or a combination thereof, into an SOH model.

In certain examples, including any of the foregoing the equivalent circuit elements are selected from the group consisting of impedance, resistance, reactance, inductance, capacitance, constant phase elements, Warburg elements, voltage, or a combination thereof.

In certain other, including any of the foregoing the equivalent circuit element is selected from the consisting of a voltage element (Vₓ), a resistance element (R₀), an impedance element (Rₓ₁), capacitance element (Cₓ₁), inductance element (Lₓ), modified inductance element (L_{y}), constant phase element (CPEₓ), Warburg element (Wₓ), or a combination thereof.

In some examples, including any of the foregoing, the methods includes generating Tₚ by inputting Zₘ or Z_{d} into an internal-temperature-calculator.

In certain other, including any of the foregoing, the methods includes generating an impedance measurement, Zₘ using a fast Fourier transformation function, or an equivalent function that computes discrete frequencies from time-domain signals, on a measured voltage (Vₘ), measured current (Iₘ), or both.

In some examples, including any of the foregoing, the methods includes generating Zₘ at least once every second, ten seconds, thirty seconds, minute, ninety seconds, two minutes, 150 seconds, three minutes, five minutes, ten minutes or twenty minutes.

In certain examples, including any of the foregoing, the methods includes generating Zₘ at least once every 1-5 seconds, 1-15 seconds, 1-30 seconds, 1-45 secnds, 1-60 seconds, 1-120 seconds, 1-240 seconds, 1-500 seconds, or 1-5,000 seconds.

In some examples, including any of the foregoing, the methods includes generating Zₘ at least once every 1-2 minutes, 1-5 minutes, 1-10 minutes, 1-15 minutes, 1-20 minutes, 1-25 minutes, 1-30 minutes, 1-35 minutes, or 1-45 minutes.

In certain other, including any of the foregoing, the methods includes generating a state-of-charge distribution (SOC_{d}) by inputting at least one of Z_{d}, V_{d}, T_{d}, and combinations thereof into a filter.

In certain examples, including any of the foregoing, the filter is a Kalman filter (KF).

In some examples, including any of the foregoing, the filter is an extended Kalman filter (EKF).

In some examples, including any of the foregoing, the filter is a linear or nonlinear joint probability distribution estimation.

In some examples, including any of the foregoing, the methods includes selecting one or more temperature look-up tables (LUT) as a function of Zm, Zd, Vd, Ip, SOC, SOCd, SOH, SOH_{d}, or a combinations thereof; wherein the LUT are previously generated for electrochemical elements having a known SOC or SOH.

In some examples, including any of the foregoing, the methods includes selecting one or more SOH look-up tables (LUT) as a function of Zm, Zd, Vd, Ip, SOC, SOCd, T, Td, or a combinations thereof, wherein the LUT are previously generated for electrochemical elements having knowns temperature or SOC.

In certain other, including any of the foregoing, the methods include actively balancing SOC between two or more of the at least two electrochemical elements using a minimization function. In some examples, SOC is balanced. In some other examples, voltage (V) is balanced. In certain examples, current (I) is balanced. In certain other examples, capacity is balanced.

In certain other, including any of the foregoing, the methods include actively balancing SOC between two or more of the at least two electrochemical cells using a minimization function. In some examples, SOC is balanced. In some other examples, V is balanced. In certain examples, I is balanced. In certain other examples, capacity is balanced.

In certain other, including any of the foregoing, the methods include actively balancing SOC between two or more of the at least two battery cells using a minimization function. In some examples, SOC is balanced. In some other examples, V is balanced. In certain examples, I is balanced. In certain other examples, capacity is balanced.

In some examples, including any of the foregoing, the methods includes actively balancing SOC between two or more of the at least two modules using a minimization function.

In some examples, including any of the foregoing, the methods includes actively balancing SOC between two or more of the at least two packs using a minimization function.

In some examples, including any of the foregoing, the method includes:
(z) determining a temperature gradient amongst two or more of the at least two electrochemical elements as a function of an EIS measurement parameter;
(aa) using an enhanced self-correcting model to estimate an OCV LUT based on the temperature of one or more of the electrochemical elements characterized by the gradient;
(ab) generating a SOC for one or more of the at least two electrochemical elements based on the OCV LUT;
(ac) actively balancing the one or more of the at least two electrochemical elements using a minimization function; or
(ad) a combination of (z), (aa), (ab), or (ac).

In certain other, including any of the foregoing, the method includes:
(ad) determining a temperature gradient amongst two or more of the at least two electrochemical elements as a function of an EIS measurement parameter;
(ae) using an equivalent circuit model to estimate an OCV LUT based on the temperature of one or more of the electrochemical elements characterized by the gradient;
(af) generating a SOC for one or more of the at least two electrochemical elements based on the OCV LUT; and
(ag) actively balancing the one or more of the at least two electrochemical elements using a minimization function.

In certain other, including any of the foregoing, the methods included using a minimization function comprises reducing the σ in SOC_{d}.

In some other examples, also set forth herein is a method for actively balancing state-of-charge (SOC), voltage (V), or both, between two or more electrochemical elements using a minimization function, including: (a) providing, or having provided, at least two electrochemical elements; (b) generating an electrochemical element (Y′) selected from an active parameter and element selector (APAES); (c) providing, or having provided, an EIS-derived impedance measurement as an active parameter (Zₘ) of Y; (d) providing, or having provided, one or more temperature look-up tables (LUT) as a function of Zₘ, state-of-charge (SOC), state-of-health (SOH), or a combinations thereof; (e) estimating the temperature of Y′ using the one or more LUT; (f) estimating state-of-health (SOH) of Y′ using the one or more LUT; (g) selecting a module OCV LUT based on the estimated SOH and estimated temperature in steps (e) and (f); (h) generating a predicted SOC, V, or both, for at least two of the two or more electrochemical elements based on the OCV LUT selected in step (g); and (i) actively balancing SOC, V, or both for the two or more electrochemical elements using a minimization function.

In some examples, including any of the foregoing, the methods includes repeating steps (a) through (i).

In some examples, including any of the foregoing, the LUT are previously generated for electrochemical elements having a known SOC or SOH.

In certain other, including any of the foregoing, the methods include estimating an OCV using one or more LUT.

In some examples, including any of the foregoing, the methods include using a minimization function that reduces the σ in the SOC, voltage, or SOH.

In some examples, where both scheduling a measurement and active balancing is performed, the electrochemical elements where a measurement is performed may be of different proportion than the plurality of the more than one electrochemical elements to be balanced. In an example of a lithium battery system that comprises a collection of electrically connected battery modules, where a battery module comprises a collection of electrically connected battery cells, an active measurement may be performed on a battery cell, whereas an active balancing method may be performed on battery modules.

In certain other, set forth herein, is a method for analyzing and balancing a battery in real-time, comprising:
(a) selecting at least one electrochemical cell in a module of electrochemical cells as an output from a decision calculator by inputting into the decision calculator a Distribution of at least two or more of the electrochemical cells; wherein the Distribution is a function of:
   (1) the output from a voltage-distribution calculator (V_{d});
   (2) the output from an active parameter distribution calculator (Z_{d});
   (3) the output from a temperature model (T_{d}); or
   (4) a combination thereof;
(b) generating a SOC, SOH, or V for the selected electrochemical element using EIS; and
(c) active balancing SOC, SOH, V, or a combination thereof for two or more of the electrochemical elements; and
(d) repeating steps (a), (b), and (c) at least once.

In some examples, including any of the foregoing, the methods include identifying a failure in at least one electrochemical element.

In some examples, including any of the foregoing, the methods include identifying a safety event in at least one electrochemical element.

In some examples, including any of the foregoing, the methods include not active balancing electrochemical elements identified as having a failure or a safety event.

In some examples, including any of the foregoing, the methods include active balancing SOC for two or more of the electrochemical elements using a minimization function.

In some examples, including any of the foregoing, the methods include using a minimization function that comprises reducing the σ in SOC_{d}.

In certain others, including the foregoing, the methods include using a minimization function that comprises reducing the σ in the voltage.

In some examples, including any of the foregoing, the methods include using a minimization function that comprises reducing the σ in the SOH.

Set forth herein is a method for scheduling a measurement, comprising: (a) providing, or having provided, at least two electrochemical elements; (b) inputting into a distribution-calculator the output from a voltage-distribution calculator, (V_{d}), the output from an impedance-distribution calculator, (Z_{d}), and the output from a temperature-distribution calculator, (T_{d}); (c) generating a Distribution, D′, as an output from the distribution-calculator; and (d) inputting D′ into an decision calculator; and (e) selecting at least one electrochemical element to be measured as an output from the decision calculator.

Set forth herein is a method for scheduling a measurement, comprising: (a) providing, or having provided, at least two electrochemical cells; (b) inputting into a distribution-calculator the output from a voltage-distribution calculator, (V_{d}), the output from an impedance-distribution calculator, (Z_{d}), and the output from a temperature-distribution calculator, (T_{d}); (c) generating a Distribution, D′, as an output from the distribution-calculator; and (d) inputting D′ into an decision calculator; and (e) selecting at least one electrochemical cell to be measured as an output from the decision calculator.

In certain examples, the methods herein are performed in the order in which the steps are recited.

### IV. Computer Programs

Also set forth herein in certain examples is a non-transitory computer readable medium encoded with instructions that, when executed in hardware, perform a method set forth in the instant specification.

Also set forth herein in certain examples a computer program product configured to perform the method, a method set forth in the instant specification.

### V. Examples

Battery samples used include battery cells and battery modules purchased from various sources. These include used Nissan LEAF generation 1 battery modules of Lithium Manganese Oxide (LMO) chemistry that are 7.4V nominal and 60 Ah capacity. The Nissan LEAF generation 1 battery module comprises four total pouch cells electrically connected in a 2-series, 2-parallel configuration. Battery samples used for testing also include Samsung 18650 cylindrical type cells of Nickel Manganese Cobalt (NMC) chemistry that are 3.7V nominal and 3000 mAh capacity. Battery samples used for testing also include lithium-iron phosphate (LFP) battery modules from Valence that are 12.8V nominal and 138 Ah capacity. These LFP battery modules comprise of over 300 18650-type cylindrical cells electrically connected in a combination of series and parallel configurations. The above are examples of electrochemical elements that the described system and method can be used on.

Electrical impedance spectroscopy was performed using several instruments. One such instrument is a Gamry Potentiostat Interface 5000E, which can perform EIS on electrochemical cells up to 5V and up to 3.5 Aᵣₘₛ EIS current. Another such instrument used during testing is a product developed by ReJoule, Inc that can perform EIS on electrochemical elements up to several hundred volts, and up to 10 Aᵣₘₛ.

The electronics and printed circuit board (PCB) assemblies were developed by ReJoule.

### Example 1

This example demonstrates an implementation of the method illustrated in FIG. 4. An example implementation is set forth in FIG. 2.

In this example, as also shown in FIG. 2, the implementation starts at step 202 and includes gathering passive measurements. These passive measurements include an electrochemical element surface temperature, electrochemical element voltage, and electrochemical element current. Step 202 also includes checking for the most up-to-date parameters.

The parameters which are checked for their most up-to-date values include, but are not limited to, a passive temperature measurement (Tₚ), a passive voltage measurement (Vₚ), or a passive current measurement (Iₚ). In one example, Tₚ, Vₚ, and Iₚ are measured with respect to a module. In another example, Tₚ, Vₚ, and Iₚ are measured with respect to a battery cell. In yet another example, Tₚ, Vₚ, and Iₚ are measured with respect to an electrochemical element. The parameters which are checked for their most up-to-date values may also include, but are not limited to, a voltage distribution (V_{d}), a temperature distribution (T_{d}), or an active parameter distribution (Z_{d}). The parameters which are checked for their most up-to-date values may also include, but are not limited to, a measured active parameter (Zₘ) or a state-of-health distribution (SOH_{d}). V_{d}, T_{d}, Z_{d}, Zₘ, and SOH_{d} may be measured with respect to a module, a battery cell, an electrochemical element, or a combination thereof.

Step 204 includes inputting the passive temperature measurements into the temperature model (404) block. Step 204 also includes inputting the passive voltage measurements into the voltage distribution (402) block. Step 204 also includes updating parameters. As shown in FIG. 4, step 204 may be carried out by inputting Vₚ into the voltage distribution (402) to generate a voltage distribution (V_{d}). As shown in FIG. 4, step 204 may be carried out by inputting Tₚ into the temperature model (404) to generate a temperature distribution (T_{d}).

Step 206 includes determining whether an active temperature measurement or an active capacity measurement is possible based on steps 202 and 204. An active temperature measurement is possible when, for example, a T_{d} includes a position associated with an electrochemical element which has a non-zero, finite value. An active temperature measurement is not possible when, for example, T_{d} includes a position associated with an electrochemical element which has a zero value. An active capacity measurement is possible when, for example, V_{d} includes a position associated with an electrochemical element which has a finite and stable value. An active capacity measurement is not possible when, for example, V_{d} includes a position associated with an electrochemical element which has an infinite or unstable value. An example of an unstable value is when a voltage measurement has multiple peaks or valleys within a short duration of time. Another example of an unstable value is when a voltage measurement has an infinite, zero, or negative value. Another example of an unstable value is when a voltage measurement sees an extreme change within a short period of time, where the extreme voltage change can be defined per the application. For example, an extreme change could include a less than 1V change within a 1 second timeframe. Additional criteria may be included in the decision making algorithm used to determine whether an active temperature measurement or an active capacity measurement is possible based on steps 202 and 204.

Step 208 includes generating a selection for either active temperature measurement or active capacity measurement. Step 208 also includes selecting a target device-under-test (DUT) based on steps 202, 204, and 206. For example, in step 202 and 204, V_{d} may include a position associated with an electrochemical element which has a minimum value, and may include a series of other positions associated with other electrochemical elements which have a value closer to 4.1 V. Based on a criteria, the electrochemical element which has a maximum voltage value may be selected as a target DUT. Based on a criteria, a selection for either an active temperature measurement or an active capacity measurement will be generated.

Step 210 includes updating filter parameters from either the active temperature measurement or the active capacity measurement selection generated at step 208. Parameters may include active measurement frequency range, number of active measurement waveforms, duration of active measurement, active measurement sensor sensitivity, active measurement magnitude, an electrochemical element voltage range during the active measurement, maximum passive current change during an active measurement, rate of passive current change during an active measurement, passive temperature measurement range during an active measurement, and any safety criteria that may disrupt an active measurement.

Step 212 includes performing either an active temperature measurement or an active capacity measurement on the selected target DUT. For example, an active capacity measurement may be performed on the selected target DUT which has a minimum voltage relative to the other electrochemical elements in the system.

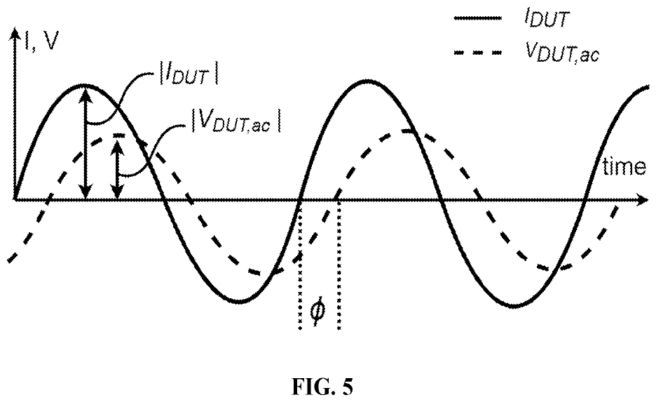

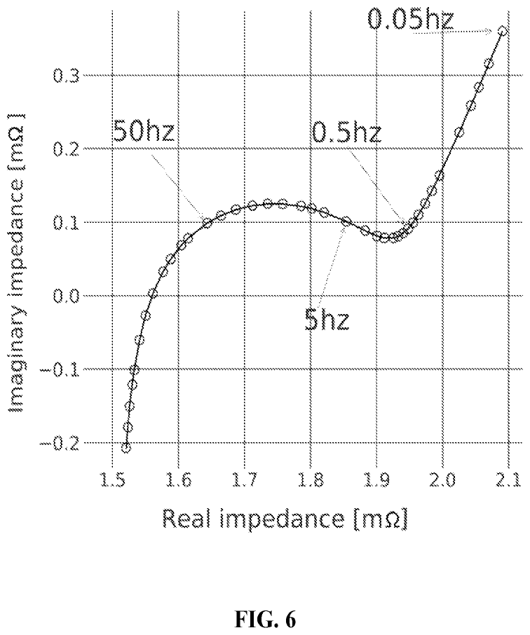

In one example of Step 212, an AC voltage pulse is applied to a DUT, which in this specific example is a battery cell within a battery module. The DUT's current (I_{DUT}) and voltage (V_{DUT}) response is observed and recorded, as in FIG. 5. The phase difference between I_{DUT} and V_{DUT} is shown as Φ in FIG. 5, which is a representative drawing. The difference in amplitude between I_{DUT} and V_{DUT} is shown as the difference in absolute magnitude of |I_{DUT}| and |V_{DUT.ac}| in FIG. 5. The response of the DUT to the applied pulse can be plotted as in FIG. 6 as the Imaginary impedance as a function of the Real impedance as is typically done for electrochemical impedance spectroscopy analysis. FIG. 6 was generated using Gamry INterface 5000E potentiostat on Nissan LEAF generation 1 battery module.

Step 214 includes filtering either the active temperature measurement or the active capacity measurement. The filtering may be accomplished with analog or digital methods. Analog or digital filtering methods may include low pass filters, high pass filters, band pass filters, notch filters, finite impulse response filters, infinite impulse response filters, multirate filters, adaptive filters, or other such methods that reject unwanted noise in a signal. Filtering methods may also include outlier detection methods and anomaly detection methods.

After step 214 a decision is made as to whether the result of step 214 qualifies as a pass or not. If the result of step 214 does not qualify as a pass, step 204 is repeated followed by steps 206, 208, 210, 212, and 214, as set forth above. If the result of step 214 does qualify as a pass, then the next step is step 216. Pass and fail criteria may include pass/fail thresholds for metrics such as signal-to-noise ratio of the measurement, total harmonic distortion in a measurement signal, maximum and minimum signal range within a sample, change in electrochemical element passive measurements during a measurement time period, and presence of outliers.

Step 216 includes inputting a filtered impedance measurement for the DUT into the temperature model 404 or the SOH model 412 as a function of whether step 208 generates a selection for active temperature measurement or active capacity measurement, respectively.

Step 218 includes processing the filtered impedance measurement for the DUT, as selected at step 216.

Step 216 may include inputting an active parameter measurement (e.g., an active impedance measurement distribution, Z_{d}) for the DUT into the temperature model 404 or the SOH model 412 as a function of whether step 208 generates a selection for active temperature measurement or active capacity measurement, respectively.

Step 218 includes processing the active parameter measurement for the DUT, as selected at step 216.

As shown in FIG. 2, the implementation ends after step 218. However, another implementation may be repeated thereafter.

### Example 2

This example demonstrates an implementation of the method of actively balancing SOC_{d}, V_{d}, SOH_{d}, or all three, between two or more electrochemical elements using a minimization function.

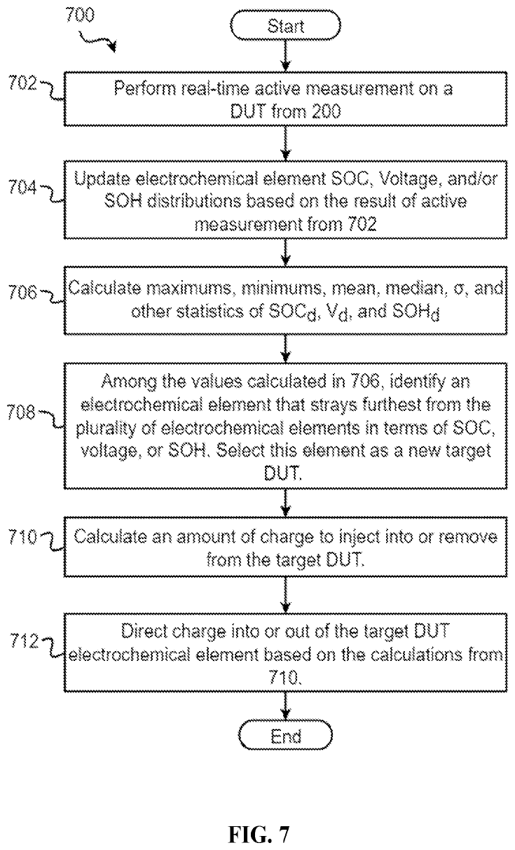

In this example, as also shown in FIG. 7, the implementation of a minimization function starts at step 702 and includes performing an active measurement on the DUT from Example 1.

In one example of step 702, an active temperature measurement is performed.

In some others, an active capacity measurement is performed in step 702.

In some others, no active measurement is completed in step 702 due to the active parameter calculator rejecting the measurement due to some error or fault condition. In this example, the implementation of the minimization function may continue to step 704 with system parameters that are not updated, or the implementation may repeat step 702 until an active measurement is completed.

After performing step 702, the electrochemical element distributions such as SOC_{d}, SOH_{d}, T_{d}, and V_{d} are updated in step 704, and statistics on the measured values such as mean, median, maximums, minimums, and o are calculated in step 706.

Step 708 includes taking the information from step 702, step 704, and step 706 to identify a new target DUT that is an electrochemical element (112) block that is most unlike the other electrochemical elements in terms of SOC, voltage, or SOH.

Step 710 includes calculating an amount of charge to inject into or remove from the target DUT.

In another example, step 710 includes calculating a power level and a duration to perform a charge or a discharge, or both, on the target DUT.

In another example, step 710 includes calculating a current level and a duration to perform a charge or a discharge, or both, on the target DUT.

In some other, step 710 includes calculating target SOC σ to achieve.

In some other, step 710 includes calculating target voltage σ to achieve.

In some other, step 710 includes calculating target SOH σ to achieve

Step 712 includes directing charge into or out of the target DUT based on the calculated instructions from step 710. This power transfer between electrochemical elements is often referred to as balancing. The act of power transfer may include electronic systems such as dc-dc converters, de-ac converters, linear power regulators, or other such systems that may convert electrical power from a de electrochemical element to another form of electrical power.

In some examples, the act of converting electrical power in step 712 may involve the active measurement control and sensing (104) block. The Active Measurement Control and Sensing (104) block may perform power conversion from one electrochemical element (112) to another electrochemical element (112). In some other, the Active Measurement Control and Sensing (104) block may also perform power conversion from a single electrochemical element (112) to the plurality of electrochemical elements that are electrically connected in a series combination, a parallel configuration, or a combination of series and parallel configurations.

In some examples, step 712 may include a short burst of power on the matter of 1 milliseconds to several seconds (s). In some others, step 712 may include a series of power bursts that represents a longer duration of 1s to several hours to reach a target instruction set in step 710. For longer duration balancing, the overall balancing may be interrupted by other activities where power flow into an electrochemical element may be disrupted. Events that may interrupt long duration balancing may include high external charge or discharge events, large fluctuations in ambient temperatures, breaching electrochemical element minimum or maximum voltage levels, or other such events that may lead to a change in electrochemical element state. These events may also prompt the system to perform an active measurement to update electrochemical element parameters.

In some others, step 712 may combine instructions from 200 to perform an active measurement while performing a balancing function.

### Example 3

This example demonstrates an implementation of the method of actively balancing SOC_{d}, V_{d}, SOH_{d}, or all three, between two or more electrochemical elements using a minimization function, and identifying warnings, fault conditions, failures, or safety events in real-time.

An active temperature measurement is performed on an electrochemical storage system with a plurality of electrochemical elements electrically connected together. From the active temperature measurement, the electrochemical storage management system determines that at least one electrochemical element within a plurality of electrically connected electrochemical elements is experiencing an abnormally high temperature event. An abnormally high temperature may be defined as a predefined high temperature threshold. In another example, an abnormally high temperature may also be defined as the measured or predicted temperature of at least one electrochemical element being statistically significant compared to the mean or median of the plurality of electrochemical elements measured or predicted temperatures. The abnormally high temperature may be detected during a high C-rate fast charging event, during a high D-rate discharge event, during some nonzero current event, or during a zero current event.

In an example, when the electrochemical storage management system detects this abnormally high temperature, a failure flag is set such that the electrochemical storage system shuts down operation and enters a faulted state. In the faulted state, the electrochemical storage system may no longer accept charge or discharge energy to a load, and the system may no longer be used for its intended purpose until the faulted state is reset.

In some others, when the electrochemical storage management system detects this abnormally high temperature, a warning flag is set, and an operator or a higher level management system is alerted. When the warning flag is set, the electrochemical storage system may or may not accept charge or discharge energy to a load, and the system may or may not be used for its intended purpose until the warning flag is reset.

In the example, the electrochemical storage management system may be in the act of performing a balancing operation when a warning flag or the fault flag is set. The electrochemical storage management system may choose to continue the balancing operation, or the electrochemical storage management system may choose to exit the balancing operation.

### Example 4

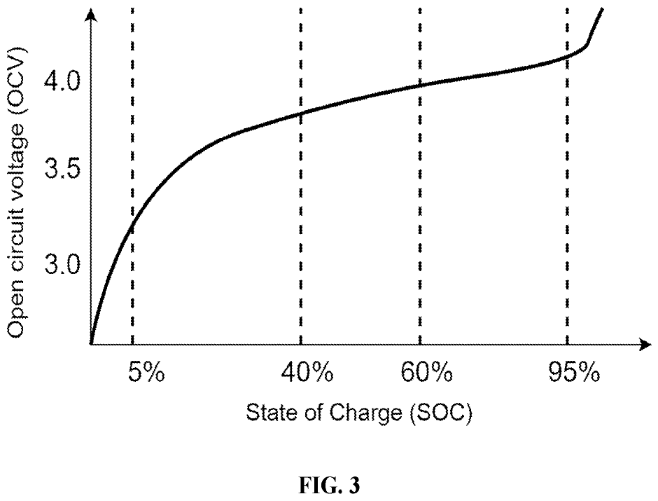

An example of a graph that is used to generate a OCV LUT is in FIG. 3. FIG. 3 was generated using the NMC 3.7V nominal Samsung 18650 cell. FIG. 3 shows the association of OCV with SOC for a tested lithium-ion battery cell electrochemical element. In this example, a lithium-ion battery cell was the electrochemical element. This plot was generated by first charging a battery cell to maximum charge using a constant-current constant-voltage (CC-CV) method, where the CC-CV current and voltages are determined by the battery manufacturer, then discharging the fully charged battery cell at a low discharge rate of C/20 at a constant temperature. The current and voltage of electrochemical element may be monitored at regular time intervals to record the experiment data. The capacity over time of the cell may be recorded to determine the relative SOC % of the cell with respect to the voltage with reference to the manufacturer capacity rating. The minimum operating voltage of the electrochemical element is represented on the lower voltage end of the SOC curve, and the maximum operating voltage of the electrochemical element is represented on the higher voltage end of the SOC curve.

The embodiments and examples described above are intended to be merely illustrative and non-limiting. Those skilled in the art will recognize or will be able to ascertain using no more than routine experimentation, numerous equivalents of specific compounds, materials and procedures. All such equivalents are considered to be within the scope and are encompassed by the appended claims.

What is claimed is:

1. A method for scheduling a measurement, comprising:
(a) providing, or having provided, at least two electrochemical elements;
(b) inputting into an active parameter and element selector (APAES):
(1) a passive current measurement (Iₚ);
(2) an asynchronous output from a system controller;
(3) an output from a voltage-distribution calculator (V_{d});
(4) an output from an active parameter distribution calculator (Z_{d});
(5) an output from a temperature model (T_{d}); or
(6) a combination of (1), (2), (3), (4), and/or (5);
(c) generating from the APAES:
(1) an active parameter output (D′); and
(2) a selected electrochemical element (Y′);
(d) inputting D′ and Y′ into an active parameter actuator and calculator; and
(e) performing, or having performed, an active parameter measurement to generate at least one active parameter output (Zₘ) from Y′; and
(f) inputting Zₘ into an active parameter distribution calculator to generate a second active parameter distribution (Z_{d}′);
(g) inputting V_{d}, Z_{d}, and T_{d} into a state-of-health (SOH) model; and
(h) generating an SOH model output (SOH_{d}) from the SOH model.

2. The method of claim 1, wherein step (e) comprises analyzing Y′ by a measurement selected from the group consisting of electrochemical impedance spectroscopy (EIS), pulse test, hybrid pulse power characterization (HPPC), galvanostatic intermittent titration technique (GITT), potentiostatic intermittent titration technique (PITT), and combinations thereof.

3. The method of claim 2, wherein Zₘ is an impedance measurement.

4. (canceled)

5. The method of claim 2, wherein the analysis includes both a discharge pulse and a charge pulse.

6. The method of claim 1, comprising measuring the temperature, voltage, or impedance of Y′.

7. The method of claim 1, wherein the at least two electrochemical elements are battery cells within a module or pack.

8. (canceled)

9. (canceled)

10. The method of claim 1, wherein the real-time active parameter and element selector comprises a filter.

11. The method of claim 10, wherein the filter is a Kalman filter, an extended Kalman filter (EKF), a linear joint probability distribution estimation, or a nonlinear joint probability distribution estimation.

12. The method of claim 1, wherein generating from the APAES a selected Y′ is as a function of:
(i) local maximum voltage (V), local minimum V, mean V, or median V;
(j) local maximum temperature (T), local minimum T, median T;
(k) local maximum impedance (Z), local minimum Z, or median Z; or
(l) a combination of (i), (j), and/or (k).

13. (canceled)

14. (canceled)

15. The method of claim 1, wherein:
(m) V_{d} is generated by inputting a measured voltage (Vₘ) or passively determined voltage (Vₚ) into a voltage-distribution-calculator;
(n) Zₘ is generated by inputting an active voltage measurement (V_{d}) or active current measurement (Iₐ), or both, and T_{d}, into an active parameter actuator and calculator;
(o) T_{d} is generated by inputting a passively measured temperature (Tₚ) and Z_{d}, or Z_{d}′ into a temperature model;
(p) Z_{d} or Z_{d}′ is generated by inputting Zₘ into an active parameter distribution calculator; and
(q) SOH_{d} is generated by inputting a measured or determined state-of-health (SOH) into a SOH model.

16. The method of claim 15, wherein:
Vₘ or Vₚ is selected from cell voltage, a module voltage, a pack voltage, or a combination thereof;
Zₘ is selected from impedance, reactance, an equivalent circuit element from a model for one or more of the at least two electrochemical elements, or a combination thereof;
T_{d} is selected from an electrochemical element surface temperature, electrochemical element internal temperature, a module temperature, or combinations thereof; and
SOH_{d} is determined for an electrochemical element by inputting Z_{d}, T_{d}, V_{d}, Iₚ, or a combination thereof, into an SOH model.

17. (canceled)

18. (canceled)

19. The method of claim 16, further comprising generating T_{d} by inputting Zₘ or Z_{d} into an internal-temperature-calculator.

20. (canceled)

21. (canceled)

22. (canceled)

23. (canceled)

24. The method of claim 1, further comprising generating a state-of-charge (SOC) by inputting at least one of Z_{d}, V_{d}, T_{d}, Iₚ, or combinations thereof into a filter.

25. The method of claim 24, wherein the filter is a Kalman Filter, an extended Kalman filter (EKF), a linear joint probability distribution estimation, or a nonlinear joint probability distribution estimation.

26. The method of claim 1, comprising actively balancing SOC between two or more of the at least two electrochemical elements using a minimization function.

27. The method of claim 1, comprising selecting one or more temperature look-up tables (LUT) as a function of Zₘ, Z_{d}, V_{d}, Iₚ, SOC, SOC_{d}, SOH, SOH_{d}, or a combinations thereof; wherein the LUT are previously generated for electrochemical elements having a known SOC or SOH.

28. The method of claim 1, comprising selecting one or more SOH look-up tables (LUT) as a function of Zₘ, Z_{d}, V_{d}, Iₚ, SOC, SOC_{d}, T, T_{d}, or a combinations thereof, wherein the LUT are previously generated for electrochemical elements having knowns temperature or SOC.

29. (canceled)

30. (canceled)

31. (canceled)

32. A method for actively balancing SOC, voltage (V), SOH, or all three, between two or more electrochemical elements using a minimization function, comprising:
(a) providing, or having provided, at least two electrochemical elements;
(b) generating an electrochemical element (Y′) selected from an active parameter and element selector (APAES);
(c) providing, or having provided, an EIS-derived impedance measurement as an active parameter (Zₘ) of Y′;
(d) providing, or having provided, one or more temperature look-up tables (LUT) as a function of Zₘ, state-of-charge (SOC), state-of-health (SOH), or a combinations thereof;
(e) estimating the temperature of Y′ using the one or more LUT;
(f) estimating state-of-health (SOH) of Y′ using the one or more LUT;
(g) selecting a module OCV LUT based on the estimated SOH and estimated temperature in steps (e) and (f);
(h) generating a predicted SOC, V, or both, for at least two of the two or more electrochemical elements based on the OCV LUT selected in step (g); and
(i) actively balancing SOC, V, or both for the two or more electrochemical elements using a minimization function.

33. (canceled)

34. (canceled)

35. (canceled)

36. (canceled)

37. A method for analyzing and balancing an electrochemical storage system in real-time, comprising:
(a) selecting at least one electrochemical element in a collection of electrochemical elements as an output from a decision calculator by inputting into the decision calculator a Distribution of at least two or more of the electrochemical elements; wherein the Distribution is a function of:
(1) the output from a voltage-distribution calculator (V_{d});
(2) the output from an active parameter distribution calculator (Z_{d});
(3) the output from a temperature model (T_{d}); or
(4) a combination thereof;
(b) generating a SOC, SOH, or V for the selected electrochemical element using Z_{d}; and
(c) active balancing SOC, SOH, V, or a combination thereof for two or more of the electrochemical elements; and
(d) repeating steps (a), (b), and (c) at least once.

38.-47. (canceled)
